(19) United States
(12) Patent Application Publication
(10) Pub. No.: US 2016/0315277 A1
(43) Pub. Date: Oct. 27, 2016

(54) MOISTURE BARRIER FILM FOR ORGANIC-INORGANIC HYBRID PEROVSKITE PHOTOVOLTAIC CELL INCLUDING IONIC POLYMER, PHOTOVOLTAIC CELL INCLUDING THE MOISTURE BARRIER FILM AND METHOD FOR FABRICATING THE PHOTOVOLTAIC CELL

(71) Applicant: KOREA INSTITUTE OF SCIENCE AND TECHNOLOGY, Seoul (KR)

(72) Inventors: Hae Jung SON, Seoul (KR); Min Jae KO, Seoul (KR); Doh-Kwon LEE, Seoul (KR); Jin Young KIM, Seoul (KR); Jai Kyeong KIM, Seoul (KR); Jae Hoon YUN, Seoul (KR); Hyun Soo CHO, Seoul (KR); Yujeong KIM, Seoul (KR)

(21) Appl. No.: 15/053,121

(22) Filed: Feb. 25, 2016

(30) Foreign Application Priority Data
Apr. 27, 2015 (KR) 10-2015-0058722

(51) Int. Cl. H01L 51/44; H01L 51/42

(52) U.S. Cl. CPC H01L 51/448; H01L 51/4213

(57) ABSTRACT

Disclosed is a moisture barrier film for an organic-inorganic hybrid photovoltaic cell which includes an ionic polymer. Also disclosed is an organic-inorganic hybrid photovoltaic cell including the moisture barrier film. The photovoltaic cell has a structure in which the moisture barrier film including an ionic polymer is formed on an absorber layer including an organic-inorganic hybrid perovskite compound. Due to this structure, the moisture barrier film effectively protects the organic-inorganic hybrid perovskite absorber layer, which is very susceptible to moisture, and other constituent layers, from moisture from the external environment so that excellent characteristics of the photovoltaic cell can be maintained for a long time. In other words, the moisture barrier film including an ionic polymer is interposed between the absorber layer and a hole transport layer or between the hole transport layer and a second electrode to enhance the physical and chemical binding therebetween.

### CROSS-REFERENCE TO RELATED APPLICATIONS

This application claims priority under 35 U.S.C. §119 to Korean Patent Application No. 10-2015-0058722 filed on Apr. 27, 2015 in the Korean Intellectual Property Office, the disclosure of which is incorporated herein by reference in its entirety.

### BACKGROUND OF THE INVENTION

1. Field of the Invention

The present invention relates to a moisture barrier film for an organic-inorganic hybrid photovoltaic cell including an ionic polymer. More specifically, the present invention relates to a moisture barrier film for an organic-inorganic hybrid photovoltaic cell including an ionic polymer that can effectively prevent moisture adsorption and ingress to protect an organic-inorganic hybrid perovskite absorber layer from moisture, an organic-inorganic hybrid photovoltaic cell with improved energy conversion efficiency and stability including the moisture barrier film, and a method for fabricating the photovoltaic cell.

2. Description of the Related Art

Photovoltaic cells (i.e. solar cells) refer to devices capable of converting solar energy into electrical energy. Specifically, photovoltaic cells are based on the photovoltaic effect, which occurs when light incident on a photosensitive material produces electrons and holes to generate a current and a voltage.

Such photovoltaic cells can produce electrical energy from clean solar energy as the ultimate source of all kinds of energy. Under these circumstances, there has been much research aimed at the development of photovoltaic cells as alternative energy sources.

Initially, n-p diodes of inorganic compound semiconductors, such as silicon or gallium arsenide (GaAs), were used as semiconductor-based solar cells. However, such solar cells are quite expensive for their performance because silicon materials and wafers constitute at least 40% of the total fabrication costs. Low absorption coefficients of the solar cells increase the thicknesses of the solar cells, leading to high fabrication costs.

As solutions to the above problems, thin-film amorphous silicon solar cells have been developed. However, such solar cells have low conversion efficiency and require vacuum processes, imposing a burden of high equipment costs. These disadvantages make the solar cells difficult to use practically.

Organic-inorganic hybrid solar cells and dye-sensitized solar cells using reduced amounts of silicon materials have been studied in earnest for the purpose of cost saving.

Organic-inorganic hybrid solar cells and dye-sensitized solar cells are reported to have power conversion efficiencies of 20% or higher. However, these solar cells were found to suffer from electrolyte leakage and volatilization, causing deterioration of characteristics and reliability. In efforts to solve such problems, gel electrolytes and solid electrolytes have been developed but they are unsatisfactory in photoelectric conversion efficiency and are difficult to produce. Furthermore, solar cells developed hitherto have a common problem in that they have poor life characteristics, resulting in considerable deterioration of performance within several days or weeks after driving.

Particularly, dye-sensitized solar cells use metal complexes, generally ruthenium complexes, as dyes. In such dye-sensitized solar cells, dyes, such as ruthenium complexes, require a long time for adsorption and absorber layers should be thick enough to achieve high power conversion efficiency.

In attempts to solve such problems, solar cells have been developed that employ perovskite dyes instead of ruthenium complexes. However, perovskite solar cells are unstable to moisture, and as a result, their performance deteriorates rapidly during driving.

### SUMMARY OF THE INVENTION

The present invention has been made in view of the above problems, and it is one object of the present invention to provide an ionic polymer solution for the formation of a moisture barrier film of an organic-inorganic hybrid perovskite photovoltaic cell that can protect a moisture-susceptible organic-inorganic perovskite absorber layer against moisture present in the external environment to maintain the performance of the absorber layer for a long time, and a moisture barrier film formed using the ionic polymer solution.

It is a further object of the present invention to provide an organic-inorganic hybrid photovoltaic film that has improved moisture stability, achieving high photoelectric conversion efficiency even under high humidity conditions, and an organic-inorganic hybrid photovoltaic cell including the photovoltaic film.

It is another object of the present invention to provide a method for fabricating the organic-inorganic hybrid photovoltaic cell on an industrial scale.

One aspect of the present invention provides an ionic polymer solution for the formation of a moisture barrier film of an organic-inorganic hybrid perovskite photovoltaic cell which includes an ionic polymer and a solvent, the ionic polymer being represented by Formula 1:

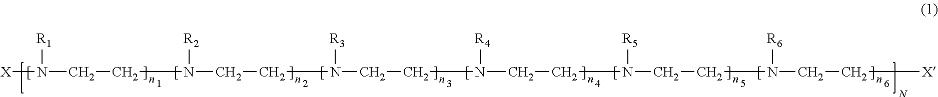

wherein X is selected from the group consisting of substituted or unsubstituted amino groups, C₁-C₄₀ alkylamino groups, and substituted or unsubstituted C₁-C₃₀ alkyl groups, X′ is selected from the group consisting of substituted or unsubstituted amino groups, C₁-C₄₀ alkylamino groups, and substituted or unsubstituted C₁-C₃₀ alkyl groups, R₁ to R₆ may be identical to or different from each other and are each independently selected from the group consisting of a hydrogen atom, a carbonyl group, a hydroxyl group, a nitro group, an amino group, substituted or unsubstituted amino groups, and substituted or unsubstituted C₁-C₃₀ alkyl groups, n₁ to n₆ are each independently 1 or 0, with the proviso that at least one of n₁ to n₆ is 1, and N is an integer from 5 to 100,000.

The term “substituted” in the definition of “substituted or unsubstituted” refers to substitution with a substituent selected from the group consisting of a deuterium atom, a hydrogen atom, a hydroxyl group, a nitro group, an amino group, a carbonyl group, straight or branched C₁-C₂₄ alkyl groups, and C₁-C₄₀ alkylamino groups.

A further aspect of the present invention provides a moisture barrier film for an organic-inorganic hybrid perovskite photovoltaic cell which includes the ionic polymer represented by Formula 1.

Another aspect of the present invention provides an organic-inorganic hybrid photovoltaic film and an organic-inorganic hybrid photovoltaic cell, each of which includes the moisture barrier film.

Yet another aspect of the present invention provides a method for fabricating an organic-inorganic hybrid photovoltaic cell, including I) forming an electron transport layer on a first electrode, II) forming an absorber layer including an organic-inorganic hybrid perovskite compound on the electron transport layer, III) applying a solution including a conductive organic semiconductor compound to the absorber layer and drying the solution to form a hole transport layer, and IV) forming a second electrode on the hole transport layer wherein the ionic polymer solution is applied to the absorber layer or the hole transport layer to form a moisture barrier film prior to at least one of steps III) and IV).

The photovoltaic cell of the present invention has a structure in which the moisture barrier film including an ionic polymer is formed on the absorber layer including an organic-inorganic hybrid perovskite compound. Due to this structure, the moisture barrier film effectively protects the organic-inorganic hybrid perovskite absorber layer, which is very susceptible to moisture, and the other constituent layers, from moisture from the external environment so that excellent characteristics of the photovoltaic cell can be maintained for a long time.

In other words, the moisture barrier film including an ionic polymer is interposed between the absorber layer and the hole transport layer or between the hole transport layer and the second electrode to enhance the physical and chemical binding therebetween. The moisture barrier film can effectively block and absorb moisture entering from the outside, enabling the photovoltaic cell to maintain its excellent characteristics even under high humidity conditions.

In addition, the organic-inorganic hybrid photovoltaic cell of the present invention can be fabricated in a simple manner despite its improved structure to achieve improved life characteristics. Therefore, the organic-inorganic hybrid photovoltaic cell of the present invention can be fabricated on a large scale.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1a is a cross-sectional view of an organic-inorganic hybrid photovoltaic cell according to one embodiment of the present invention;

FIG. 1b is a cross-sectional view of an organic-inorganic hybrid photovoltaic cell according to a further embodiment of the present invention;

FIG. 1c is a cross-sectional view of an organic-inorganic hybrid photovoltaic cell according to another embodiment of the present invention;

FIG. 2 shows time-dependent changes in the normalized current density of organic-inorganic hybrid photovoltaic cells fabricated in Examples 1 and 2 and Comparative Example 1 at a relative humidity (RH) of 85%;

FIG. 3 shows time-dependent changes in the normalized open circuit voltage of organic-inorganic hybrid photovoltaic cells fabricated in Examples 1 and 2 and Comparative Example 1 at a RH of 85%;

FIG. 4 shows time-dependent changes in the normalized fill factor of organic-inorganic hybrid photovoltaic cells fabricated in Examples 1 and 2 and Comparative Example 1 at a RH of 85%;

FIG. 5 shows time-dependent changes in the normalized energy conversion efficiency of organic-inorganic hybrid photovoltaic cells fabricated in Examples 1 and 2 and Comparative Example 1 at a RH of 85%;

FIG. 6 shows time-dependent UV-Visible absorption spectra of an organic-inorganic hybrid photovoltaic film produced in Example 3 at a RH of 85%;

FIG. 7 shows time-dependent UV-Visible absorption spectra of an organic-inorganic hybrid photovoltaic film produced in Comparative Example 3 at a RH of 85%;

FIG. 8 shows changes in the normalized absorbance of organic-inorganic hybrid photovoltaic films produced in Example 3 and Comparative Example 3 at a wavelength of 760 nm in the UV-Visible region as a function of exposure time to moisture;

FIG. 9 shows changes in the normalized absorbance of organic-inorganic hybrid photovoltaic films produced in Example 3 and Comparative Example 3 at a wavelength of 480 nm in the UV-Visible region as a function of exposure time to moisture;

FIG. 10 shows images showing changes in the surface morphology of organic-inorganic hybrid photovoltaic films produced in Example 3 and Comparative Example 3 at 85% RH and 25° C. in the dark as a function of exposure time to moisture;

FIGS. 11a and 11b show a scanning electron microscopy image and an atomic force microscopy image of an organic-inorganic hybrid photovoltaic film produced in Comparative Example 3 before exposure to moisture, respectively;

FIGS. 12a and 12b show a scanning electron microscopy image and an atomic force microscopy image of an organic-inorganic hybrid photovoltaic film produced in Comparative Example 3 after exposure to moisture for 19 days, respectively;

FIGS. 13a and 13b show a scanning electron microscopy image and an atomic force microscopy image of an organic-inorganic hybrid photovoltaic film produced in Example 3 before exposure to moisture, respectively; and

FIGS. 14a and 14b show a scanning electron microscopy image and an atomic force microscopy image of an organic-inorganic hybrid photovoltaic film produced in Example 3 after exposure to moisture for 19 days, respectively.

### DETAILED DESCRIPTION OF THE INVENTION

The present invention will now be described in more detail.

One aspect of the present invention is directed to an ionic polymer solution for the formation of a moisture barrier film of an organic-inorganic hybrid perovskite photovoltaic cell which includes an ionic polymer and a solvent, the ionic polymer being represented by Formula 1:

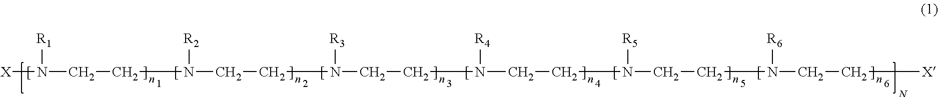

wherein X is selected from the group consisting of substituted or unsubstituted amino groups, C₁-C₄₀ alkylamino groups, and substituted or unsubstituted C₁-C₃₀ alkyl groups, X′ is selected from the group consisting of substituted or unsubstituted amino groups, C₁-C₄₀ alkylamino groups, and substituted or unsubstituted C₁-C₃₀ alkyl groups, R₁ to R₆ may be identical to or different from each other and are each independently selected from the group consisting of a hydrogen atom, a carbonyl group, a hydroxyl group, a nitro group, an amino group, substituted or unsubstituted amino groups, and substituted or unsubstituted C₁-C₃₀ alkyl groups, n₁ to n₆ are each independently 1 or 0, with the proviso that at least one of n₁ to n₆ is 1, and N is an integer from 5 to 100,000.

The ionic polymer solution can be used to form a moisture barrier film that protects an organic-inorganic hybrid perovskite compound used in an absorber layer of a photovoltaic cell against moisture present in the external environment. The ionic polymer of Formula 1 is substituted with various substituents, such as X, X′, and R₁ to R₆.

Specific examples of the alkyl groups include methyl, ethyl, propyl, isobutyl, sec-butyl, tert-butyl, pentyl, iso-amyl, hexyl, heptyl, octyl, stearyl, trichloromethyl, and trifluoromethyl groups. At least one hydrogen atom of each alkyl group may be substituted with a deuterium atom, a hydroxyl group, a nitro group, a substituted or unsubstituted amino group (—NH₂, —NH(R) or —N(R′)(R″), where R, R′, and R″ are each independently a C₁-C₂₄ alkyl group (in this case, the amino group is called an “alkylamino” group)), a straight or branched C₁-C₂₄ alkyl group or a carbonyl group.

As described above, the term “substituted” in the definition of “substituted or unsubstituted” refers to substitution with a substituent selected from the group consisting of a deuterium atom, a hydrogen atom, a hydroxyl group, a nitro group, an amino group, a carbonyl group, straight or branched C₁-C₂₄ alkyl groups, and C₁-C₄₀ alkylamino groups.

Specifically, the ionic polymer of Formula 1 may be selected from the group consisting of, but not limited to, the following structures of Formulae 2 to 19:

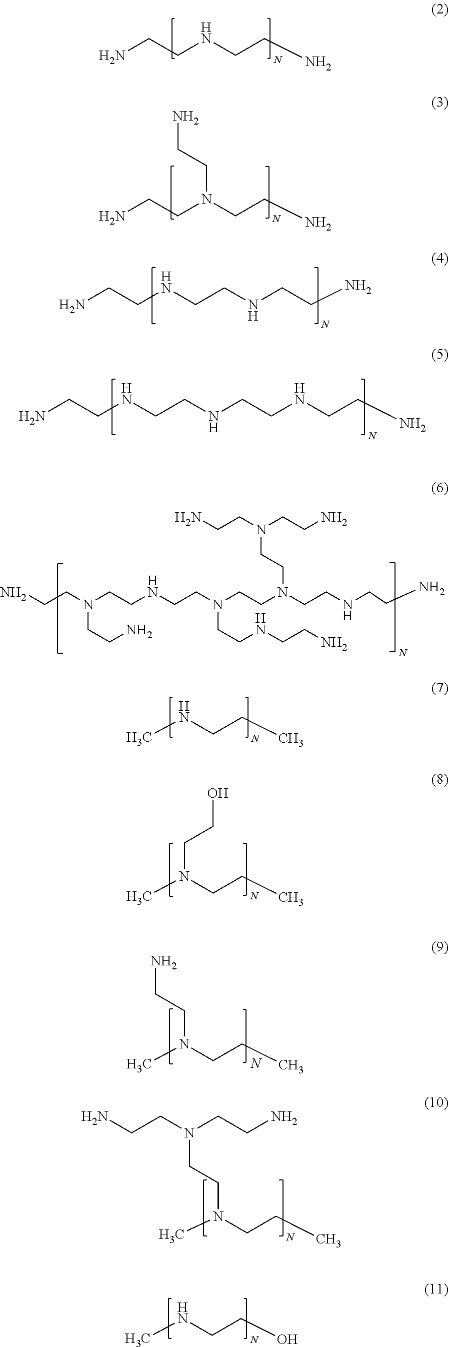

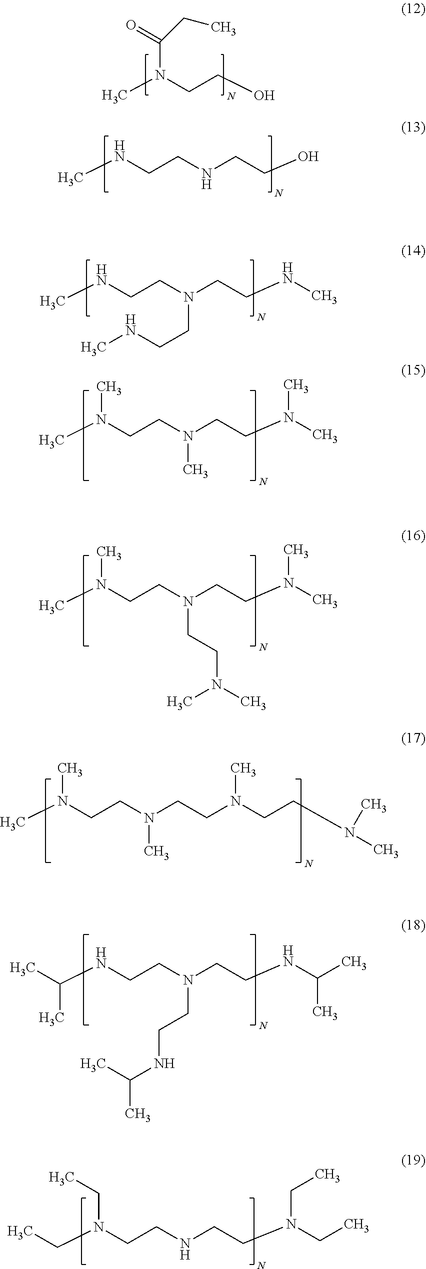

wherein each N is independently an integer from 5 to 100,000.

The solvent included in the ionic polymer solution may be selected from the group consisting of ethanol, methanol, propanol, isopropanol, butanol, acetone, pentane, toluene, benzene, diethyl ether, methyl butyl ether, N-methylpyrrolidone (NMP), tetrahydrofuran (THF), dimethylformamide (DMF), dimethylacetamide (DMAC), dimethyl sulfoxide (DMSO), carbon tetrachloride, dichloromethane, dichloroethane, trichloroethylene, chloroform, chlorobenzene, dichlorobenzene, trichlorobenzene, cyclohexane, cyclopentanone, cyclohexanone, dioxane, terpineol, methyl ethyl ketone, o-xylene, and combinations thereof. Preferably, the solvent is selected from the group consisting of toluene, dimethylformamide, methanol, hexane, o-xylene, chlorobenzene, ethylene acetate, 2-propanol, tetrahydrofuran, N-methylpyrrolidinone, and combinations thereof, which do not chemically react with materials for an absorber layer, an electron transport layer, and a hole transport layer.

The amount of the ionic polymer dissolved in the solvent is in the range of 4 to 30 parts by weight, based on 100 parts by weight of the solvent. The performance of the moisture barrier film of the organic-inorganic hybrid perovskite photovoltaic cell varies depending on the mixing ratio between the ionic polymer and the solvent, as described in the Examples section that follows. The performance of the moisture barrier film affects the energy conversion efficiency and water resistance of the organic-inorganic hybrid perovskite photovoltaic cell. In view of this, it is preferred that the mixing ratio between the ionic polymer and the solvent is in the range defined above.

The dissolution of 0.1 to 3 parts by weight of the ionic polymer in 100 parts by weight of the solvent ensures high energy conversion efficiency of the photovoltaic cell but causes low water resistance of the photovoltaic cell, and as a result, problems of conventional organic-inorganic hybrid perovskite absorber layers remain unsolved.

Meanwhile, the dissolution of 35 parts by weight or more (for example, 35 to 50 parts by weight) of the ionic polymer in 100 parts by weight of the solvent ensures satisfactory water resistance of the photovoltaic cell but leads to lower energy conversion efficiency of the photovoltaic cell than that of conventional photovoltaic cells, making it meaningless to use an organic-inorganic hybrid perovskite absorber layer with high performance. Therefore, it is preferred to dissolve 4 to 30 parts by weight of the ionic polymer in 100 parts by weight of the solvent when both energy conversion efficiency and water resistance of the photovoltaic cell are taken into consideration.

The number average molecular weight of the ionic polymer is preferably in the range of 25,000 to 1,000,000. Within this range, the ionic polymer can be formed into a thin film by coating.

A further aspect of the present invention is directed to a moisture barrier film for an organic-inorganic hybrid perovskite photovoltaic cell which includes an ionic polymer represented by Formula 1:

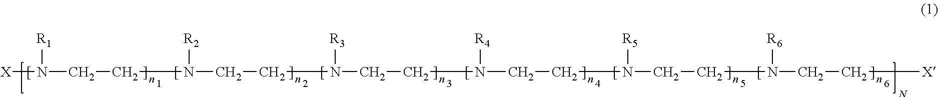

wherein X is selected from the group consisting of substituted or unsubstituted amino groups, C₁-C₄₀ alkylamino groups, and substituted or unsubstituted C₁-C₃₀ alkyl groups, X′ is selected from the group consisting of substituted or unsubstituted amino groups, C₁-C₄₀ alkylamino groups, and substituted or unsubstituted C₁-C₃₀ alkyl groups, R₁ to R₆ may be identical to or different from each other and are each independently selected from the group consisting of a hydrogen atom, a carbonyl group, a hydroxyl group, a nitro group, an amino group, substituted or unsubstituted amino groups, and substituted or unsubstituted C₁-C₃₀ alkyl groups, n₁ to n₆ are each independently 1 or 0, with the proviso that at least one of n₁ to n₆ is 1, and N is an integer from 5 to 100,000.

The term “substituted” in the definition of “substituted or unsubstituted” refers to substitution with a substituent selected from the group consisting of a deuterium atom, a hydrogen atom, a hydroxyl group, a nitro group, an amino group, a carbonyl group, straight or branched C₁-C₂₄ alkyl groups, and C₁-C₄₀ alkylamino groups.

Specifically, the ionic polymer of Formula 1 may be selected from the group consisting of, but not limited to, the following structures of Formulae 2 to 19:

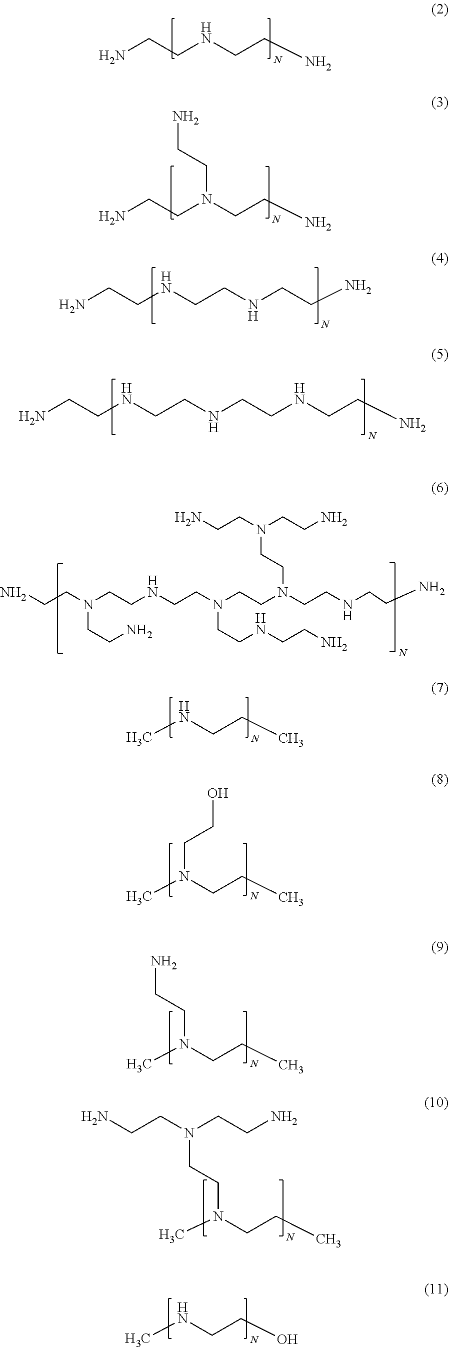

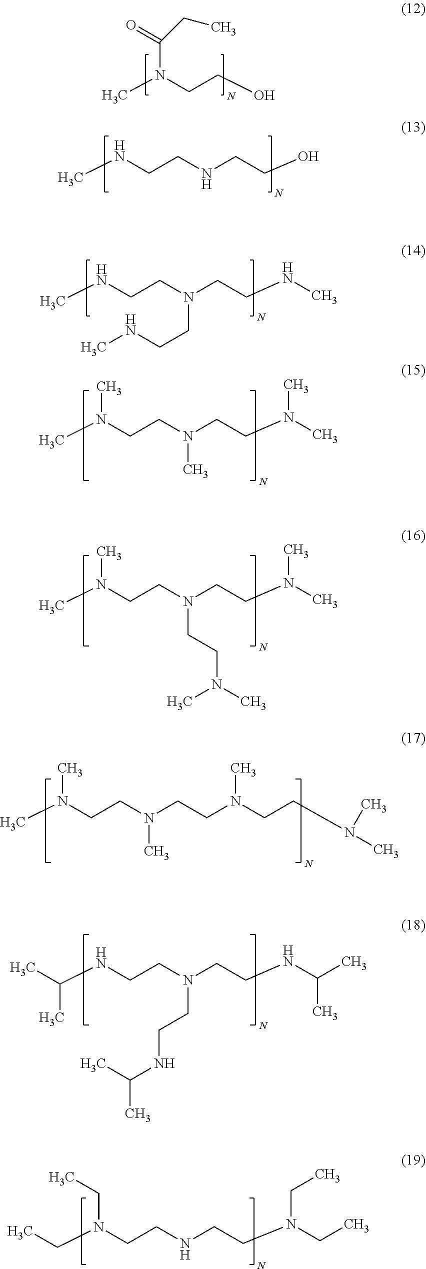

wherein each N is independently an integer from 5 to 100,000.

The number average molecular weight of the ionic polymer is preferably in the range of 1,000 to 1,000,000. Within this range, the ionic polymer can be formed into a thin film by coating.

The thickness of the moisture barrier film is preferably from 1 to 60 nm. Moisture from the external environment cannot be sufficiently absorbed by the moisture barrier film thinner than 1 nm. Meanwhile, no electric current flows through the moisture barrier film thicker than 60 nm. It is most preferred that the thickness of the moisture barrier film does not exceed 20 nm in order for an organic-inorganic hybrid photovoltaic cell including the moisture barrier film to achieve a photoelectric conversion efficiency of at least 8%.

Another aspect of the present invention is directed to an organic-inorganic hybrid photovoltaic cell including the moisture barrier film wherein the moisture barrier film includes the ionic polymer represented by Formula 1.

The moisture barrier film including the ionic polymer is preferably interposed between a hole transport layer and a second electrode or between an absorber layer and the hole transport layer. Alternatively, the moisture barrier film may be provided in two. In this case, one of the moisture barrier films may be interposed between a hole transport layer and a second electrode and the other moisture barrier film may be interposed between an absorber layer and the hole transport layer.

The moisture barrier film absorbs moisture from the external environment and blocks the ingress of the moisture into the absorber layer while promoting the migration of ions therethrough, Accordingly, the formation of the moisture barrier film is effective in improving the moisture resistance (i.e. life characteristics) of the photovoltaic cell without deteriorating the performance of the photovoltaic cell. This effect can provide a solution to problems encountered with conventional organic-inorganic hybrid photovoltaic cells including an organic-inorganic hybrid perovskite compound as a material for an absorber layer. For example, the performance of the organic-inorganic hybrid photovoltaic cell according to the present invention can be prevented from deteriorating rapidly from the moment the organic-inorganic hybrid photovoltaic cell is exposed to moisture present in the external environment.

It is most preferred that the moisture barrier film is disposed between an absorber layer including an organic-inorganic hybrid perovskite compound and a hole transport layer close to the absorber layer. The reason why this arrangement is preferred is that the moisture barrier film disposed between an absorber layer and a hole transport layer can more immediately and rapidly absorb moisture and block the ingress of the moisture into the absorber layer than the moisture barrier film disposed at a position other than the position between an absorber layer and a hole transport layer. This arrangement can further delay the time it takes for the structure to collapse when the absorber layer is exposed to moisture.

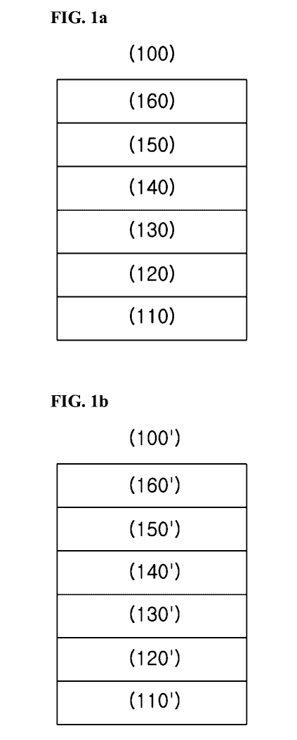

Specifically, the organic-inorganic hybrid photovoltaic cell of the present invention includes an absorber layer including a compound having a perovskite structure with high power conversion efficiency capable of absorbing sunlight to generate excitons, a hole transport layer including a conductive organic semiconductor compound, and an electron transport layer including an n-type semiconductor compound or metal oxide, as well as the moisture barrier film including the ionic polymer. The organic-inorganic hybrid photovoltaic cell of the present invention is small in thickness and has improved water resistance and durability, achieving excellent life characteristics. In addition, the organic-inorganic hybrid photovoltaic cell of the present invention can maintain its high conversion efficiency even under high humidity conditions. Exemplary structures of the organic-inorganic hybrid photovoltaic cell are illustrated in FIGS. 1a, 1b, and c.

FIG. 1a illustrates an organic-inorganic hybrid photovoltaic cell 100 according to one embodiment of the present invention. Referring to FIG. 1a, the organic-inorganic hybrid photovoltaic cell 100 includes a first electrode 110, an electron transport layer 120, an absorber layer 130, a moisture barrier film 140, a hole transport layer 150, and a second electrode 160 disposed in this order from the bottom. The moisture barrier film 140 is formed between the absorber layer 130 and the hole transport layer 150.

FIG. 1b illustrates an organic-inorganic hybrid photovoltaic cell 100′ according to a further embodiment of the present invention. The organic-inorganic hybrid photovoltaic cell 100′ includes a first electrode 110′, an electron transport layer 120′, an absorber layer 130′, a hole transport layer 140′, a moisture barrier film 150′, and a second electrode 160′ disposed in this order from the bottom. The organic-inorganic hybrid photovoltaic cell 100′ is characterized in that the moisture barrier film 150′ is formed between the hole transport layer 140′ and the second electrode 160′.

FIG. 1c illustrates an organic-inorganic hybrid photovoltaic cell 100″ according to another embodiment of the present invention. The organic-inorganic hybrid photovoltaic cell 100″ includes a first electrode 110″, an electron transport layer 120″, an absorber layer 130″, a moisture barrier layer 140″, a hole transport layer 150″, a moisture barrier film 170″, and a second electrode 160″ disposed in this order from the bottom. The organic-inorganic hybrid photovoltaic cell 100″ is characterized in that the moisture barrier layer 140″ is formed between the absorber layer 130″ and the hole transport layer 150″ and the moisture barrier film 170″ is formed between the hole transport layer 150″ and the second electrode 160′.

The absorber layer 130 includes an organic-inorganic hybrid perovskite (hereinafter also referred to simply as “organic-inorganic perovskite”) compound capable of absorbing light to generate excitons rather than a dye.

The organic-inorganic hybrid perovskite compound has a low bandgap, is capable of efficiently absorbing sunlight, can form coarse grains, and enables efficient exciton separation and transport. Accordingly, the organic-inorganic hybrid perovskite compound is very desirable as a photosensitizer that absorbs sunlight to create photoelectron-photohole pairs.

The organic-inorganic hybrid perovskite compound is not particularly limited and may be any compound having a perovskite structure in which coexisting organic and inorganic materials are bonded to each other. Preferably, the organic-inorganic hybrid perovskite compound is selected from the group consisting of Bi₂S₃, Bi₂Se₃, InP, InCuS₂, In(CuGa)Se₂, Sb₂S₃, Sb₂Se₃, SnSₓ (x is a real number satisfying 1≦x≦2), NiS, CoS, FeS_{y} (y is a real number satisfying 1≦y≦2), In₂S₃, MoS, MoSe, and combinations thereof.

The absorber layer 130 including the organic-inorganic hybrid perovskite compound is simple to form and provides high performance even at a small thickness. Despite these advantages, the photosensitizer tends to decompose upon contact with moisture, resulting in extremely poor water resistance of the absorber layer.

Due to this problem, the presence of moisture in air is liable to deteriorate the performance of organic-inorganic hybrid photovoltaic cells, making them unsuitable for long-term use. As a result, organic-inorganic hybrid photovoltaic cells have not been put into practical use despite their significant advantages.

As a solution to the problem, the present invention proposes an improved structure of an organic-inorganic hybrid photovoltaic cell using a perovskite compound with high photoelectric conversion efficiency to achieve improved water resistance and durability.

The first electrode 110 may have a multilayer structure including a substrate and is preferably a transparent substrate provided with a transparent electrode. There is no particular restriction on the first electrode 110. The first electrode 110 may be any transparent electrode or substrate that is commonly used in the field of organic-inorganic hybrid photovoltaic cells. Preferably, the first electrode 110 is fluorine doped tin oxide (FTO) or indium doped tin oxide (ITO). The transparent substrate is preferably glass.

The electron transport layer 120 provides paths through which electrons can move smoothly and may include an n-type semiconductor compound or metal oxide.

The electron transport layer 120 may include metal oxide particles. In this case, the electron transport layer 120 may form a porous structure with open pores. The absorber layer 130 may be formed in contact with the metal oxide particles present in the pores of the porous electron transport layer 120.

The metal oxide particles included in the electron transport layer 120 are not limited and may be particles of any metal oxide commonly used in the art. Preferably, the metal oxide is selected from the group consisting of Ti oxides, In oxides, Zn oxides, Sn oxides, W oxides, Nb oxides, Mo oxides, Mg oxides, Zr oxides, Sr oxides, Yr oxides, La oxides, V oxides, Al oxides, Sc oxides, Sm oxides, Ga oxides, SrTi oxides, and composites thereof.

Alternatively, the electron transport layer 120 may include an n-type semiconductor compound. The n-type semiconductor compound is not particularly limited and examples thereof include polymer compounds whose skeleton is an aromatic carboxylic anhydride or an imide compound, such as fullerenes and octaazaporphyrins. The use of a fullerene derivative with improved solubility is most preferred. The fullerene derivative may also form a porous structure.

The electron transport layer 120 may have a porous structure. In this case, the electron transport layer 120 ensures a smooth flow of electrons therethrough due to large specific surface area. In addition, the electron transport layer 120 has a large contact area with the absorber layer, resulting in an increase in photosensitive area. Accordingly, excitons are transported to the adjacent metal oxide particles before decay and can be easily dissociated into electrons and holes.

The electron transport layer 120 may have a thickness of 0.1 to 5 μm. If the electron transport layer 120 is thinner than 0.1 μm, its contact area with the absorber layer 130 is small, resulting in poor efficiency. Meanwhile, if the electron transport layer 120 is thicker than 5 μm, the moving distance of photoelectrons is long, resulting in poor efficiency.

It is preferred that the electron transport layer 120 is effective in blocking holes from moving towards the first electrode 110. For this purpose, a metal oxide thin film may be further disposed between the electron transport layer 120 and the first electrode 110.

The moisture barrier film 140 may be formed between the absorber layer 130 and the hole transport layer 150 or between the hole transport layer 150 and the second electrode 160. Alternatively, the moisture barrier film 140 may be provided in two. In this case, one of the moisture barrier films 140 may be formed between the absorber layer 130 and the hole transport layer 150 and the other the moisture barrier film 140 may be formed between the hole transport layer 150 and the second electrode 160. As a result, the moisture barrier film 140 is in contact with the absorber layer 130 and the hole transport layer 150 or with the hole transport layer 150 and the second electrode 160 to form a heterojunction interface.

Specifically, the moisture barrier film 140 may be laminated on the absorber layer 130 including the organic-inorganic hybrid perovskite compound or on the hole transport layer 150. In the case where the moisture barrier film 140 are provided in two, one of the moisture barrier films 140 may be formed on the absorber layer 130 and the other moisture barrier films 140 may be formed on the hole transport layer 150.

The moisture barrier film 140 may include an ionic polymer that can block the ingress of moisture into the absorber layer while promoting the migration of ions therethrough.

The ionic polymer is represented by Formula 1:

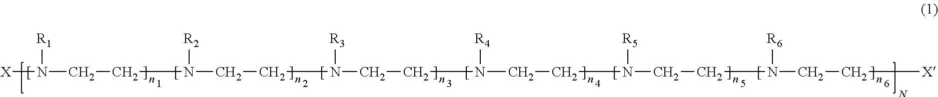

wherein X is selected from the group consisting of substituted or unsubstituted amino groups, C₁-C₄₀ alkylamino groups, and substituted or unsubstituted C₁-C₃₀ alkyl groups, X′ is selected from the group consisting of substituted or unsubstituted amino groups, C₁-C₄₀ alkylamino groups, and substituted or unsubstituted C₁-C₃₀ alkyl groups, R₁ to R₆ may be identical to or different from each other and are each independently selected from the group consisting of a hydrogen atom, a carbonyl group, a hydroxyl group, a nitro group, an amino group, substituted or unsubstituted amino groups, and substituted or unsubstituted C₁-C₃₀ alkyl groups, n₁ to n₆ are each independently 1 or 0, with the proviso that at least one of n₁ to n₆ is 1, and N is an integer from 5 to 100,000.

The term “substituted” in the definition of “substituted or unsubstituted” refers to substitution with a substituent selected from the group consisting of a deuterium atom, a hydrogen atom, a hydroxyl group, a nitro group, an amino group, a carbonyl group, straight or branched C₁-C₂₄ alkyl groups, and C₁-C₄₀ alkylamino groups.

Specific examples of the alkyl groups include methyl, ethyl, propyl, isobutyl, sec-butyl, tert-butyl, pentyl, iso-amyl, hexyl, heptyl, octyl, stearyl, trichloromethyl, and trifluoromethyl groups. At least one hydrogen atom of each alkyl group may be substituted with a deuterium atom, a hydroxyl group, a nitro group, a substituted or unsubstituted amino group (—NH₂, —NH(R) or —N(R′)(R″), where R, R′, and R″ are each independently a C₁-C₂₄ alkyl group (in this case, the amino group is called an “alkylamino” group)), a straight or branched C₁-C₂₄ alkyl group or a carbonyl group.

As described above, the term “substituted” in the definition of “substituted or unsubstituted” refers to substitution with a substituent selected from the group consisting of a deuterium atom, a hydrogen atom, a hydroxyl group, a nitro group, an amino group, a carbonyl group, straight or branched C₁-C₂₄ alkyl groups, and C₁-C₄₀ alkylamino groups.

Specifically, the ionic polymer of Formula 1 may be selected from the group consisting of, but not limited to, the following structures of Formulae 2 to 19:

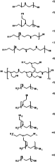

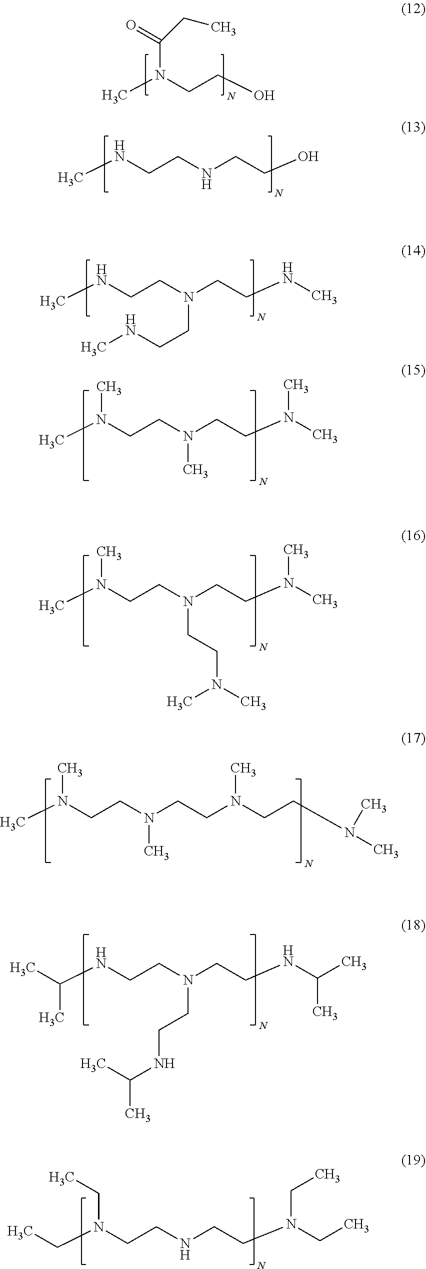

wherein each N is independently an integer from 5 to 100,000.

Due to the presence of the ionic polymer having the above structure, the moisture barrier film 140 interacts physically and chemically with compounds present in the absorber layer 130 and/or the hole transport layer 150. This interaction is effective in blocking the ingress of moisture from the outside. Accordingly, when the organic-inorganic hybrid photovoltaic cell of the present invention is exposed to air or stored in a humid place, the moisture barrier film 140 can block the ingress of moisture because it more rapidly absorbs moisture from the outside than the absorber layer 130 does.

The ion-conductive material included in the moisture barrier film 140 is a spherical insulating organic compound and has the ability to effectively block the ingress of moisture from the external environment into the absorber layer 130 due to its good intermolecular connection.

The moisture barrier film 140 may be in the form of a 1 to 60 nm thick layer between the absorber layer 130 and the hole transport layer 150. Moisture from the external environment cannot be sufficiently absorbed by the moisture barrier film 140 thinner than 1 nm. Meanwhile, no electric current flows through the moisture barrier film 140 thicker than 60 nm. It is preferred that the thickness of the moisture barrier film 140 does not exceed 20 nm in order for the organic-inorganic hybrid photovoltaic cell to achieve a photoelectric conversion efficiency of at least 8%.

Portions of the moisture barrier film 140 may be infiltrated into pores formed in the absorber layer 130 or the hole transport layer 150. This structure provides a large surface area for ion transport and a short distance for ion transport between the absorber layer 130 and the hole transport layer 150. Therefore, fast and smooth migration of ions is ensured in the moisture barrier film 140 whose portions are infiltrated into the pores compared to in the moisture barrier film 140 whose portions are not infiltrated into the pores.

The degree of partial infiltration of the moisture barrier film 140 into pores formed in the absorber layer 130 or the hole transport layer 150 can be expressed as the “infiltration depth” of the moisture barrier film 140 and may be appropriately selected depending on the size of the pores formed in the absorber layer 130 or the hole transport layer 150. Preferably, the infiltration depth of the moisture barrier film 140 is from 0.1 to 0.9 mm. If the infiltration depth of the moisture barrier film 140 into the pores formed in the absorber layer 130 or the hole transport layer 150 is less than 0.1 mm, the moisture barrier film 140 does not come into contact with the absorber layer 130 or the hole transport layer 150 so that an heterojunction interface cannot be formed, resulting in slow migration of ions. Further, the adhesion strength of the moisture barrier film 140 to the absorber layer 130 or the hole transport layer 150 is low, and as a result, the moisture barrier film 140 tends to be separated from the moisture barrier film 140 or the hole transport layer 150. Meanwhile, if the infiltration depth of the moisture barrier film 140 into the pores formed in the absorber layer 130 or the hole transport layer 150 exceeds 0.9 mm, the moisture barrier film 140 may damage the absorber layer, resulting in poor efficiency.

When the moisture barrier film 140 is formed between the hole transport layer 150 and the second electrode 160, it can be chemically and physically bound to the hole transport layer and can block external moisture from reaching the absorber layer 130, achieving sufficiently improved water resistance and durability. It is more preferred that the moisture barrier film 140 is interposed between the absorber layer 130 and the hole transport layer 150 because the absorber layer 130 can be easily protected against humidity.

The second electrode 160 formed on the hole transport layer 150 may be made of any material commonly used in the art. The material for the second electrode 160 is not particularly limited but is preferably selected from the group consisting of gold, silver, platinum, palladium, copper, aluminum, and composites thereof. The work function of the material for the second electrode 160 may be appropriately determined depending on the energy level of the highest occupied molecular orbital (HOMO) of the hole transport material.

The photovoltaic cell of the present invention may optionally further include one or more intermediate layers.

Due to its improved structure, the organic-inorganic hybrid photovoltaic cell maintains 39 to 80% of its initial energy conversion efficiency when exposed to a relative humidity of 70 to 90% for 15 to 25 days. In contrast, a conventional organic-inorganic hybrid photovoltaic cell without a moisture barrier film maintains 22% of its initial energy conversion efficiency when exposed to a relative humidity of 70 to 90% for 15 to 25 days. That is, the organic-inorganic hybrid photovoltaic cell of the present invention is excellent in terms of water resistance compared to the conventional organic-inorganic hybrid photovoltaic cell.

The electrodes may be removed from the organic-inorganic hybrid photovoltaic cell to produce an organic-inorganic hybrid photovoltaic film.

Yet another aspect of the present invention is directed to a method for fabricating the organic-inorganic hybrid photovoltaic cell, the method including I) forming an electron transport layer on a first electrode, II) forming an absorber layer including an organic-inorganic hybrid perovskite compound on the electron transport layer, III) applying a solution including a conductive organic semiconductor compound to the absorber layer and drying the solution to form a hole transport layer, and IV) forming a second electrode on the hole transport layer wherein a solution of the ionic polymer represented by Formula 1 and a solvent is applied to the absorber layer and/or the hole transport layer to form a moisture barrier film prior to at least one of steps III) and IV).

First, an electron transport layer is formed on a first electrode (I).

The electron transport layer has a porous structure. This porous structure increases the contact area of the electron transport layer with an absorber layer, which is subsequently formed on the electron transport layer, leading to a further improvement in power conversion efficiency. The electron transport layer may be formed using metal oxide particles or an n-type semiconductor compound. Particularly, the use of the metal oxide particles leads to a larger specific surface area than the use of the n-type semiconductor compound.

The metal oxide particles are not limited and may be particles of any metal oxide commonly used in the art. Preferably, the metal oxide is selected from the group consisting of Ti oxides, In oxides, Zn oxides, Sn oxides, W oxides, Nb oxides, Mo oxides, Mg oxides, Zr oxides, Sr oxides, Yr oxides, La oxides, V oxides, Al oxides, Sc oxides, Sm oxides, Ga oxides, SrTi oxides, and composites thereof.

The n-type semiconductor compound is not particularly limited and examples thereof include polymer compounds whose skeleton is an aromatic carboxylic anhydride or an imide compound, such as fullerenes and octaazaporphyrins. The use of a fullerene derivative with improved solubility is most preferred.

That is, the specific surface area and porous structure of the electron transport layer are factors that significantly affect the contact area with the absorber layer. It is thus preferred to effectively control the factors. To this end, annealing is preferably performed at a temperature of 200 to 500° C. in air.

The electron transport layer is preferably formed to a thickness of 0.1 to 5 μm.

The method of the present invention may further include forming a metal oxide thin film between the first electrode and the electron transport layer before the formation of the electron transport layer. The metal oxide thin film is preferably formed by chemical or physical deposition used in general semiconductor manufacturing processes.

The metal oxide thin film is not limited and may be a thin film of any suitable metal oxide. Preferably, the metal oxide is selected from the group consisting of Ti oxides, In oxides, Zn oxides, Sn oxides, W oxides, Nb oxides, Mo oxides, Mg oxides, Zr oxides, Sr oxides, Yr oxides, La oxides, V oxides, Al oxides, Sc oxides, Sm oxides, Ga oxides, SrTi oxides, and composites thereof. More preferred is a Ti oxide.

Thereafter, an absorber layer including an organic-inorganic hybrid perovskite compound is formed on the electron transport layer (II). The absorber layer may be simply formed by applying a solution including an organic-inorganic hybrid perovskite compound and drying the solution.

The organic-inorganic hybrid perovskite compound is not particularly limited and may be any compound having a perovskite structure in which coexisting organic and inorganic materials are bonded to each other. Preferably, the organic-inorganic hybrid perovskite compound is selected from the group consisting of Bi₂S₃, Bi₂Se₃, InP, InCuS₂, In(CuGa)Se₂, Sb₂S₃, Sb₂Se₃, SnSₓ (x is a real number satisfying 1≦x≦2), NiS, CoS, FeS_{y} (y is a real number satisfying 1≦y≦2), In₂S₃, MoS, MoSe, and combinations thereof.

Next, an ionic polymer solution including an ionic polymer and a solvent is applied to the absorber layer to form a moisture barrier film (prior to step III) or IV)). The ionic polymer is represented by Formula 1:

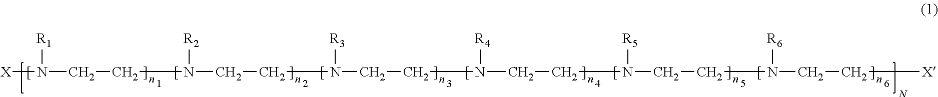

wherein X is selected from the group consisting of substituted or unsubstituted amino groups, C₁-C₄₀ alkylamino groups, and substituted or unsubstituted C₁-C₃₀ alkyl groups, X′ is selected from the group consisting of substituted or unsubstituted amino groups, C₁-C₄₀ alkylamino groups, and substituted or unsubstituted C₁-C₃₀ alkyl groups, R₁ to R₆ may be identical to or different from each other and are each independently selected from the group consisting of a hydrogen atom, a carbonyl group, a hydroxyl group, a nitro group, an amino group, substituted or unsubstituted amino groups, and substituted or unsubstituted C₁-C₃₀ alkyl groups, n₁ to n₆ are each independently 1 or 0, with the proviso that at least one of n₁ to n₆ is 1, and N is an integer from 5 to 100,000.

The term “substituted” in the definition of “substituted or unsubstituted” refers to substitution with a substituent selected from the group consisting of a deuterium atom, a hydrogen atom, a hydroxyl group, a nitro group, an amino group, a carbonyl group, straight or branched C₁-C₂₄ alkyl groups, and C₁-C₄₀ alkylamino groups.

The solvent included in the ionic polymer solution may be selected from the group consisting of ethanol, methanol, propanol, isopropanol, butanol, acetone, pentane, toluene, benzene, diethyl ether, methyl butyl ether, N-methylpyrrolidone (NMP), tetrahydrofuran (THF), dimethylformamide (DMF), dimethylacetamide (DMAC), dimethyl sulfoxide (DMSO), carbon tetrachloride, dichloromethane, dichloroethane, trichloroethylene, chloroform, chlorobenzene, dichlorobenzene, trichlorobenzene, cyclohexane, cyclopentanone, cyclohexanone, dioxane, terpineol, methyl ethyl ketone, o-xylene, and combinations thereof. Preferably, the solvent is selected from the group consisting of toluene, dimethylformamide, methanol, hexane, o-xylene, chlorobenzene, ethylene acetate, 2-propanol, tetrahydrofuran, N-methylpyrrolidinone, and combinations thereof, which do not chemically react with materials for an absorber layer, an electron transport layer, and a hole transport layer, which are formed subsequently.

Specifically, the moisture barrier film is formed such that a flow of holes from the absorber layer is not limited. To this end, the moisture barrier film may be formed by applying the ionic polymer solution of 4 to 30 parts by weight of the ionic polymer in 100 parts by weight of the solvent to the absorber layer by a coating technique selected from the group consisting of vacuum evaporation, screen printing, printing, spin coating, dipping, and ink spraying. Preferably, the moisture barrier film is formed by spin coating at 5000 rpm or more for 1 minute or more.

More specifically, the dissolution of 0.1 to 3 parts by weight of the ionic polymer in 100 parts by weight of the solvent ensures high energy conversion efficiency of the photovoltaic cell but causes low water resistance of the photovoltaic cell, and as a result, problems of conventional organic-inorganic hybrid perovskite absorber layers remain unsolved.

Meanwhile, the dissolution of 35 parts by weight or more (for example, 35 to 50 parts by weight) of the ionic polymer in 100 parts by weight of the solvent ensures satisfactory water resistance of the photovoltaic cell but leads to lower energy conversion efficiency of the photovoltaic cell than that of conventional photovoltaic cells, making it meaningless to use an organic-inorganic hybrid perovskite absorber layer with high performance. Therefore, it is preferred to dissolve 4 to 30 parts by weight of the ionic polymer in 100 parts by weight of the solvent when both energy conversion efficiency and water resistance of the photovoltaic cell are taken into consideration.

The thickness of the moisture barrier film is preferably from 1 to 60 nm. The moisture barrier film thinner than 1 nm cannot effectively block the ingress of moisture into the absorber layer. Meanwhile, the moisture barrier film thicker than 60 nm has a low absorbance, resulting in low power conversion efficiency.

Finally, a hole transport layer is formed on the moisture barrier film and a second electrode is formed thereon. The second electrode may be formed on the hole transport layer by physical vapor deposition or chemical vapor deposition.

The present invention will be explained in more detail with reference to the following examples. However, these examples are not to be construed as limiting or restricting the scope and disclosure of the invention. It is to be understood that based on the teachings of the present invention including the following examples, those skilled in the art can readily practice other embodiments of the present invention whose experimental results are not explicitly presented. It will also be understood that such modifications and variations are intended to come within the scope of the appended claims.

### PREPARATIVE EXAMPLE 1

### Preparation of Polyethyleneimine Solutions

Polyethyleneimine (PEI) was dissolved in chlorobenzene for 10 min to prepare a mixture solution having a concentration of 1-3 mg/ml. The mixture solution was diluted with chlorobenzene to concentrations of 0.1 mg/ml and 0.08 mg/ml.

The dilutions were sonicated for 15 min to prepare polyethyleneimine solutions having concentrations of 0.1 mg/ml and 0.08 mg/ml.

The polyethyleneimine (PEI) is represented by Formula 6:

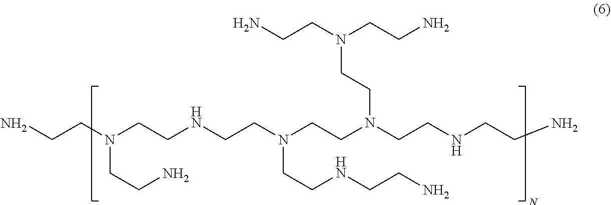

wherein N is from 100 to 1,000.

The number average molecular weight of the polyethyleneimine in the polyethyleneimine solutions was 25,000.

### PREPARATIVE EXAMPLE 2

### Preparation of Polyethyleneimine Solutions

Polyethyleneimine solutions having concentrations of 0.1 mg/ml and 0.08 mg/ml were prepared in the same manner as in Preparative Example 1, except that toluene was used instead of chlorobenzene.

The polyethyleneimine (PEI) is represented by Formula 6:

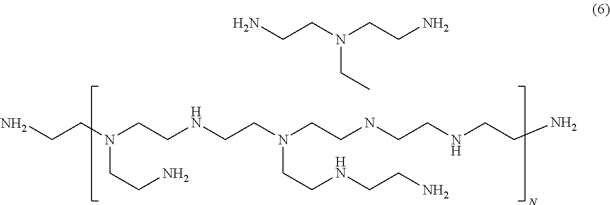

wherein N is from 100 to 1,000.

The number average molecular weight of the polyethyleneimine in the polyethyleneimine solutions was 25,000.

### PREPARATIVE EXAMPLE 3

### Preparation of Tetraethylenepentamine Solutions

Polyethyleneimine (PEI) was dissolved in chlorobenzene by sonication for 10 min to prepare a mixture solution having a concentration of 1-3 mg/ml. The mixture solution was diluted with chlorobenzene to prepare tetraethylenepentamine solutions having concentrations of 0.1 mg/ml and 0.08 mg/ml.

The tetraethylenepentamine is represented by Formula 5:

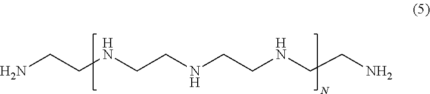

wherein N is from 100 to 1,000.

The number average molecular weight of the tetraethylenepentamine in the tetraethylenepentamine solutions was 27,000.

### PREPARATIVE EXAMPLE 4

### Preparation of 1,1,4,7,10,10-Hexamethyltriethylenetetramine Solutions

1,1,4,7,10,10-hexamethyltriethylenetetramine was dissolved in chlorobenzene by sonication for 10 min to prepare a mixture solution having a concentration of 1-3 mg/ml. The mixture solution was diluted with chlorobenzene to prepare 1,1,4,7,10,10-hexamethyltriethyl enetetramine solutions having concentrations of 0.1 mg/ml and 0.08 mg/ml.

The 1,1,4,7,10,10-hexamethyltriethylenetetramine is represented by Formula 17:

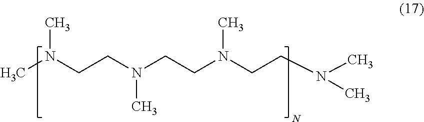

wherein N is from 100 to 1,000.

The number average molecular weight of the 1,1,4,7,10,10-hexamethyltriethylenetetramine in the 1,1,4,7,10,10-hexamethyltriethylenetetramine solutions was 29,000.

### PREPARATIVE EXAMPLE 5

### Preparation of tris(2-aminoethyl)amine Solutions

Tris(2-aminoethyl)amine was dissolved in 2-propanol by sonication for 10 min to prepare a mixture solution having a concentration of 1-3 mg/ml. The mixture solution was diluted with 2-propanol to prepare tris(2-aminoethyl)amine solutions having concentrations of 0.1 mg/ml and 0.08 mg/ml.

The tris(2-aminoethyl)amine is represented by Formula 3:

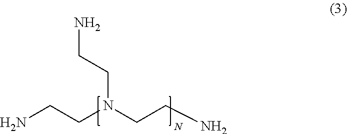

wherein N is from 100 to 1,000.

The number average molecular weight of the tris(2-aminoethyl)amine in the tris(2-aminoethyl)amine solutions was 24,000.

### PREPARATIVE EXAMPLE 6

### Preparation of tris(2-(isopropylamino)ethyl)amine Solutions

Tris(2-(isopropylamino)ethyl)amine was dissolved in o-xylene by sonication for 20 min to prepare a mixture solution having a concentration of 1-3 mg/ml. The mixture solution was diluted with o-xylene to prepare tris(2-(isopropylamino)ethyl)amine solutions having concentrations of 0.1 mg/ml and 0.08 mg/ml.

The tris(2-(isopropylamino)ethyl)amine is represented by Formula 18:

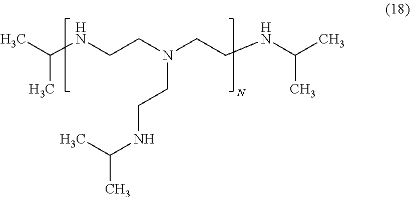

wherein N is from 100 to 1,000.

The number average molecular weight of the tris(2-(isopropylamino)ethyl)amine in the tris(2-(isopropylamino)ethyl)amine solutions was 26,000.

### PREPARATIVE EXAMPLE 7

### Preparation of tris[(2-(methylamino)ethyl] Amine Solutions

Tris[(2-(methylamino)ethyl]amine was dissolved in chlorobenzene by sonication for 20 min to prepare a mixture solution having a concentration of 1-3 mg/ml. The mixture solution was diluted with chlorobenzene to prepare tris[(2-(methylamino)ethyl]amine solutions having concentrations of 0.1 mg/ml and 0.08 mg/ml.

The tris[(2-(methylamino)ethyl]amine is represented by Formula 14:

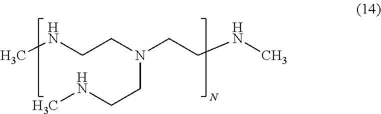

wherein N is from 100 to 1,000.

The number average molecular weight of the tris[(2-(methylamino)ethyl]amine in the tris[(2-(methylamino)ethyl]amine solutions was 25,000.

### EXAMPLE 1

### Fabrication of Organic-Inorganic Hybrid Photovoltaic Cell

A fluorine doped tin oxide (FTO) transparent conductive film was formed on a glass substrate and patterned into stripes by general photolithography and hydrochloric acid etching processes to form a transparent first electrode.

Titanium dioxide (TiO₂) nanoparticles having a particle diameter of 10-40 nm (average 25 nm) were mixed with ethanol to obtain a metal oxide paste. The metal oxide paste was spin coated on the first electrode, followed by annealing at 500° C. for 60 min to form a 200 nm thick electron transport layer.

Lead diiodide (PbI₂) was dissolved in dimethylformamide (DMF) with stirring at 80° C. for 12 h to prepare a first mixture solution. Methylammonium iodide (CH₃NH₃I) was dissolved in isopropanol (IPA) to prepare a second mixture solution. Thereafter, the first mixture was spin coated on the electron transport layer at 6500 rpm for 60 sec, the second mixture solution was spin coated thereon at 1000 rpm for 10 sec, followed by annealing on a hot plate at 100° C. for 20 min to form a perovskite absorber layer.

The 0.08 mg/ml branched polyethyleneimine (PEI) solution prepared in Preparative Example 1 was spin coated on the perovskite absorber layer at 5000 rpm for 60 sec to form a ≦10 nm thick moisture barrier film.

2,2′,7,7′-tetrakis(N,N-p-dimethoxyphenylamino)-9, 9′-spirobifluorene (Spiro-OMeTAD) was dissolved in chlorobenzene to prepare a mixture solution. To 100 parts by weight of the mixture solution were added 10 parts by weight of lithium bis(trifluoromethanesulfonyl)imide and 53 parts by weight of 4-tert-butyl pyridine. The resulting mixture was spin coated on the moisture barrier film at 2,500 rpm for 20 sec to form a hole transport layer.

Finally, gold was deposited on the hole transport layer using a thermal evaporator under a high vacuum (≦5×10⁻⁶ torr) to form a second electrode, completing the fabrication of an organic-inorganic hybrid photovoltaic cell having an area of 2.5 cm'2.5 cm.

### EXAMPLE 2

### Fabrication of Organic-Inorganic Hybrid Photovoltaic Cell

An organic-inorganic hybrid photovoltaic cell was fabricated in the same manner as in Example 1, except that the 0.1 mg/ml polyethyleneimine solution prepared in Preparative Example 1 was used to form a moisture barrier film.

### EXAMPLE 3

### Fabrication of Organic-Inorganic Hybrid Photovoltaic Film

A fluorine doped tin oxide (FTO) transparent conductive film was formed on a glass substrate and patterned into stripes by general photolithography and hydrochloric acid etching processes to form a transparent first electrode.

Titanium dioxide (TiO₂) nanoparticles having a particle diameter of 10-40 nm (average 25 nm) were mixed with ethanol to obtain a metal oxide paste. The metal oxide paste was spin coated on the first electrode, followed by annealing at 500° C. for 60 min to form a 200 nm thick electron transport layer.

Lead diiodide (PbI₂) was dissolved in dimethylformamide (DMF) with stirring at 80° C. for 12 h to prepare a first mixture solution. Methylammonium iodide (CH₃NH₃I) was dissolved in isopropanol (IPA) to prepare a second mixture solution. Thereafter, the first mixture was spin coated on the electron transport layer at 6500 rpm for 60 sec, the second mixture solution was spin coated thereon at 1000 rpm for 10 sec, followed by annealing on a hot plate at 100° C. for 20 min to form a perovskite absorber layer.

The 0.1 mg/ml branched polyethyleneimine (PEI) solution prepared in Preparative Example 1 was spin coated on the perovskite absorber layer at 5000 rpm for 60 sec to form a moisture barrier film.

2,2′,7,7′-tetrakis(N,N-p-dimethoxyphenylamino)-9, 9′-spirobifluorene (Spiro-OMeTAD) was dissolved in chlorobenzene to prepare a mixture solution having a concentration of 55.8 mg/ml. The mixture solution was spin coated on the moisture barrier film at 2,500 rpm for 20 sec to form a hole transport layer.

### COMPARATIVE EXAMPLE 1

An organic-inorganic hybrid photovoltaic cell was fabricated in the same manner as in Example 1, except that the moisture barrier layer was not formed.

### COMPARATIVE EXAMPLE 2

An organic-inorganic hybrid photovoltaic cell was fabricated in the same manner as in Example 2, except that the moisture barrier layer was not formed.

### COMPARATIVE EXAMPLE 3

An organic-inorganic hybrid photovoltaic film was fabricated in the same manner as in Example 3, except that the moisture barrier layer was not formed.

### EVALUATION EXAMPLE 1

The time-dependent characteristics of the organic-inorganic hybrid photovoltaic cells fabricated in Examples 1 and 2 and the Comparative Example 1 at 85% RH and 25° C. in the dark were analyzed and compared in order to evaluate the stabilities of the inventive organic-inorganic hybrid photovoltaic cells against moisture.

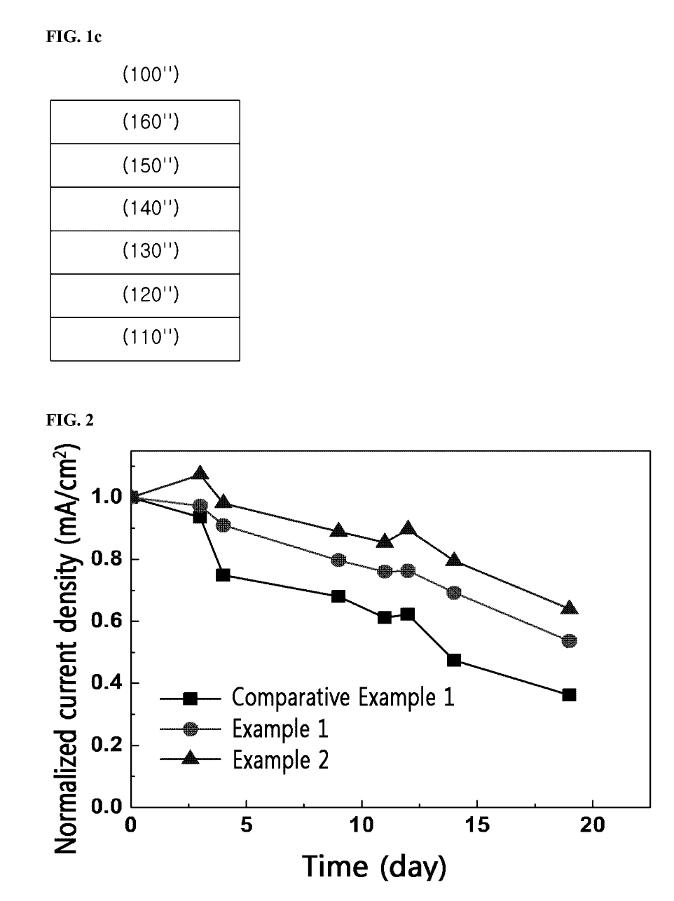

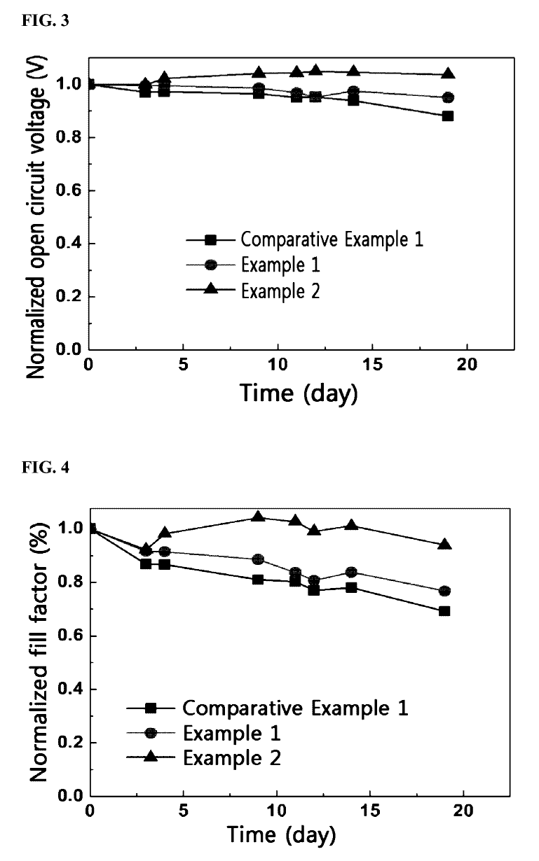

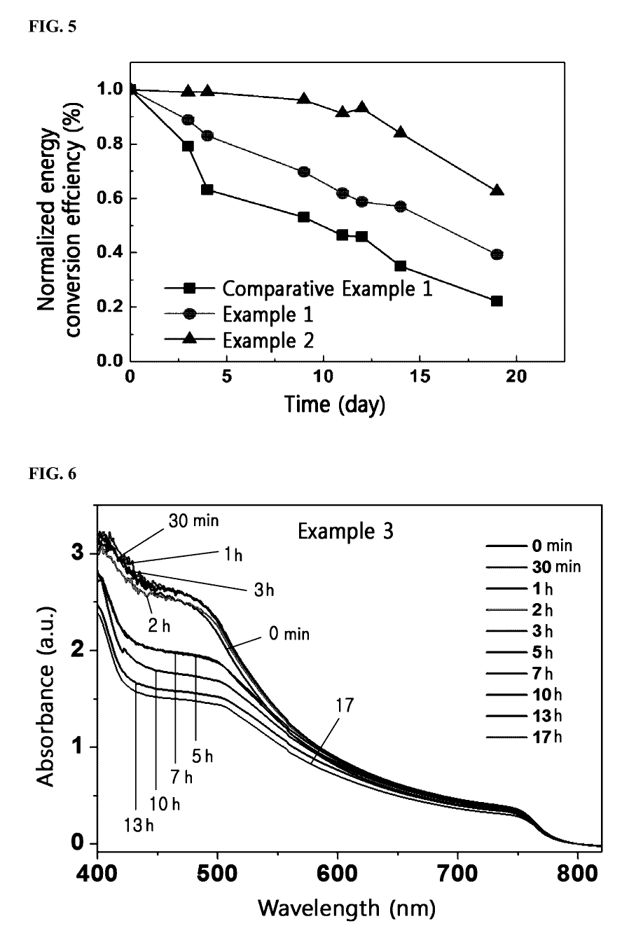

FIGS. 2, 3, 4, and 5 show time-dependent changes in the normalized current density, the normalized open circuit voltage, the normalized fill factor, and the normalized energy conversion efficiency of the organic-inorganic hybrid photovoltaic cells fabricated in Examples 1 and 2 and Comparative Example 1 at 85% RH, respectively.

The current densities, the open circuit voltages, the fill factors, and the energy conversion efficiencies of the organic-inorganic hybrid photovoltaic cells were calculated from the graphs of FIGS. 2, 3, 4, and 5, respectively. The results are shown in Table 1.

TABLE 1

| | | Current density | Open circuit | Fill factor | Energy conversion |
|---|---|---|---|---|---|
| | Time (day) | (mA/cm²) | voltage (V) | (%) | efficiency (%) |
| Example 1 | 0 | 19.0432 | 0.97413 | 62.27273 | 11.55687 |
| Example 2 | | 16.39467 | 0.94317 | 58.60867 | 9.071333 |
| Comparative | | 19.01975 | 0.98731 | 62.61306 | 11.76269 |
| Example 1 | | | | | |
| Example 1 | 3 | 18.5274 | 0.9694 | 57.0591 | 10.2699 |
| Example 2 | | 17.60333 | 0.94183 | 54.04617 | 8.982167 |
| Comparative | | 17.80092 | 0.95754 | 54.37023 | 9.311846 |
| Example 1 | | | | | |
| Example 1 | 4 | 17.326 | 0.97 | 56.9781 | 9.5994 |
| Example 2 | | 16.07533 | 0.964 | 57.522 | 8.9875 |
| Comparative | | 14.24064 | 0.95936 | 54.27718 | 7.422909 |
| Example 1 | | | | | |
| Example 1 | 9 | 15.18213 | 0.96088 | 55.149 | 8.0645 |
| Example 2 | | 14.573 | 0.9815 | 61.03225 | 8.72725 |
| Comparative | | 12.94355 | 0.95182 | 50.72473 | 6.234818 |
| Example 1 | | | | | |
| Example 1 | 11 | 14.48511 | 0.94356 | 52.133 | 7.155889 |
| Example 2 | | 14.0015 | 0.984 | 60.17225 | 8.28175 |
| Comparative | | 11.62342 | 0.93842 | 50.26708 | 5.46 |
| Example 1 | | | | | |
| Example 1 | 12 | 14.5308 | 0.928 | 50.2569 | 6.7906 |
| Example 2 | | 14.69675 | 0.98975 | 58.055 | 8.44425 |
| Comparative | | 11.84492 | 0.94085 | 48.14238 | 5.390231 |
| Example 1 | | | | | |
| Example 1 | 14 | 13.18375 | 0.94942 | 52.18817 | 6.589333 |
| Example 2 | | 13.025 | 0.98675 | 59.22975 | 7.61 |
| Comparative | | 9.018308 | 0.92746 | 48.86315 | 4.118154 |
| Example 1 | | | | | |
| Example 1 | 19 | 10.21991 | 0.92591 | 47.77764 | 4.547545 |
| Example 2 | | 10.48675 | 0.978 | 55.0305 | 5.675 |
| Comparative | | 6.884545 | 0.869 | 43.31273 | 2.615545 |
| Example 1 | | | | | |

As can be seen from FIGS. 2, 3, 4, and 5 and Table 1, all organic-inorganic hybrid photovoltaic cells showed similar performance characteristics at the initial stage but the performance characteristics of the organic-inorganic hybrid photovoltaic cell of Comparative Example 1 were considerably inferior to those of the organic-inorganic hybrid photovoltaic cells of Examples 1 and 2 with the passage of time (particularly, at 9-11 days).

On day 19, the performance characteristics of the organic-inorganic hybrid photovoltaic cell of Comparative Example 1 were reduced to half or less of those of the organic-inorganic hybrid photovoltaic cells of Examples 1 and 2.

That is, the perovskite photovoltaic cells of Examples 1 and 2 showed high open circuit voltages, current densities, fill factors, and efficiencies due to the introduction of the moisture barrier layers. The presence of the moisture barrier layers allowed the perovskite photovoltaic cells of Examples 1 and 2 to maintain their high efficiencies at a high humidity for a longer time than the perovskite photovoltaic cell of Comparative Example 1 into which a moisture barrier layer was not introduced.

The organic-inorganic hybrid photovoltaic cells of Comparative Example 1 and Examples 1 and 2 had similar energy conversion efficiencies at the initial stage, demonstrating that the moisture barrier layers could effectively block the ingress of moisture from the outside without affecting the performance of the organic-inorganic hybrid photovoltaic cells to maintain the high efficiencies of the organic-inorganic hybrid photovoltaic cells at a high humidity for a long time.

The organic-inorganic hybrid photovoltaic cell of Example 1, in which the moisture barrier film was formed using the lower concentration polyethyleneimine solution, showed a high energy conversion efficiency but had inferior water resistance compared to the organic-inorganic hybrid photovoltaic cell of Example 2.

From these results, it can be concluded that the concentrations (w/v) of the polyethyleneimine as an ionic polymer in the polyethyleneimine solutions for the formation of the moisture barrier films are preferably between 0.08 and 0.1 mg/ml but excellent life characteristics can be obtained without deterioration of energy conversion efficiency (≦4%) and water resistance until day 19 even at concentrations of 0.04 to 0.3 mg/ml.

However, if the concentration (w/v) of the ionic polymer is less than 0.04 mg/ml, high energy conversion efficiency is obtained but considerably low water resistance is caused. As a result, the absorber layer is not protected from collapse by moisture, failing to achieve improved life. If the concentration (w/v) of the polyethyleneimine as an ionic polymer in the polyethyleneimine solution exceeds 0.3 mg/ml, markedly improved resistance is achieved but low energy conversion efficiency is caused. In conclusion, it is preferred that the polyethyleneimine solution has a concentration in the range of about 0.04-0.3 mg/ml. Within this range, satisfactory energy conversion efficiency and water resistance are attained.

### EVALUATION EXAMPLE 2

The time-dependent changes in the optical properties of the organic-inorganic hybrid photovoltaic films produced in Example 3 and Comparative Example 3 were analyzed by UV-Visible spectrometry at 85% RH and 25° C. in the dark in order to investigate the influence of humidity on the inventive organic-inorganic hybrid photovoltaic film.

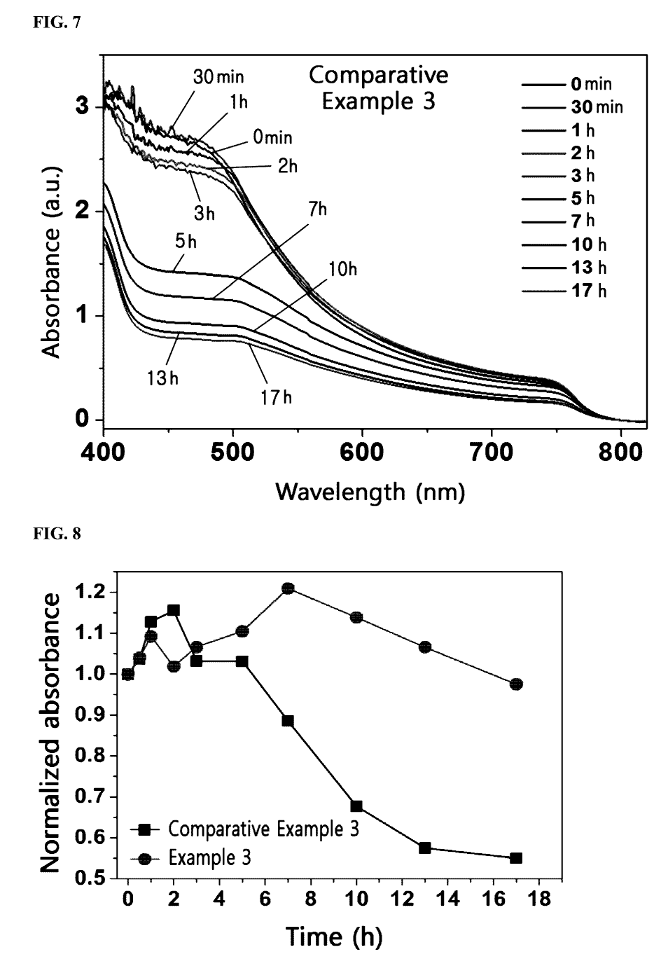

FIGS. 6 and 7 show time-dependent UV-Visible absorption spectra of the organic-inorganic hybrid photovoltaic films produced in Example 3 and Comparative Example 3 at 85% RH, respectively.

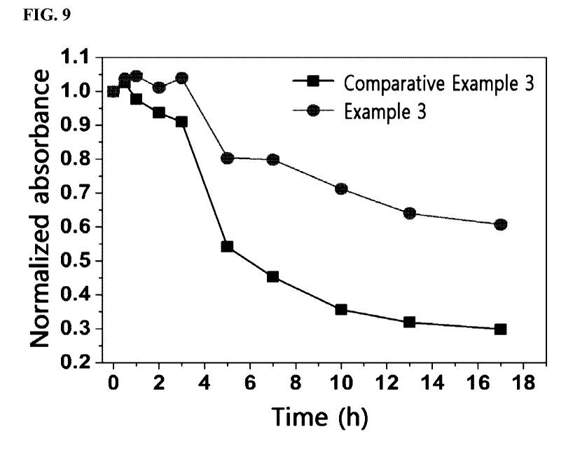

FIG. 8 shows changes in the normalized absorbance of the organic-inorganic hybrid photovoltaic films produced in Example 3 and Comparative Example 3 at a wavelength of 760 nm in the UV-Visible region as a function of exposure time to moisture and FIG. 9 shows changes in the normalized absorbance of the organic-inorganic hybrid photovoltaic films produced in Example 3 and Comparative Example 3 at a wavelength of 480 nm in the UV-Visible region as a function of exposure time to moisture.

The graphs of FIGS. 8 and 9 were obtained by normalizing the UV-Visible absorption spectra of FIGS. 6 and 7, respectively.

As shown in FIGS. 6 to 9, the organic-inorganic hybrid photovoltaic films of Example 3 and Comparative Example 3 showed similar optical properties in the first 3 days, but thereafter the optical properties of the organic-inorganic hybrid photovoltaic film of Comparative Example 3 dropped drastically.

Specifically, the initial optical properties of the organic-inorganic hybrid photovoltaic film of Example 3 were maintained substantially constant despite increasing moisture exposure time at an absorption wavelength of 760 nm, whereas the optical properties of the organic-inorganic hybrid photovoltaic film of Comparative Example 3 was drastically reduced to half of their initial values with increasing moisture exposure time at an absorption wavelength of 760 nm.

The optical properties of the organic-inorganic hybrid photovoltaic films of Example 3 and Comparative Example 3 decreased at an absorption wavelength of 480 nm. Specifically, the optical properties of the organic-inorganic hybrid photovoltaic film of Example 3 decreased by 0.3, whereas those of the organic-inorganic hybrid photovoltaic film of Comparative Example 3 decreased by 0.7 or more.

From the above results, the organic-inorganic hybrid photovoltaic film without a moisture barrier film (Comparative Example 3) showed much lower absorption properties upon long-term exposure to moisture than the organic-inorganic hybrid photovoltaic film of Example 3. The moisture barrier layer including the ionic polymer and disposed between the absorber layer and the hole transport layer can protect the absorber layer against moisture without affecting the function of the absorber layer, indicating that the optical properties can be maintained for a long time.

Excellent absorption properties of an absorber layer are related to high efficiency of an organic-inorganic hybrid solar cell including the absorber layer. Therefore, the organic-inorganic hybrid photovoltaic cells and film (Examples 1-3) can maintain their high efficiencies even under high humidity conditions for a long time compared to the organic-inorganic hybrid photovoltaic cells and film without a moisture barrier layer (Comparative Examples 1-3).

### EVALUATION EXAMPLE 3

Changes in the surface morphology of the organic-inorganic hybrid photovoltaic films produced in Example 3 and Comparative Example 3 as a function of time were analyzed in a thermostat at 85% RH and 25° C. in the dark in order to investigate the influence of humidity on the surfaces of the inventive organic-inorganic hybrid photovoltaic film.

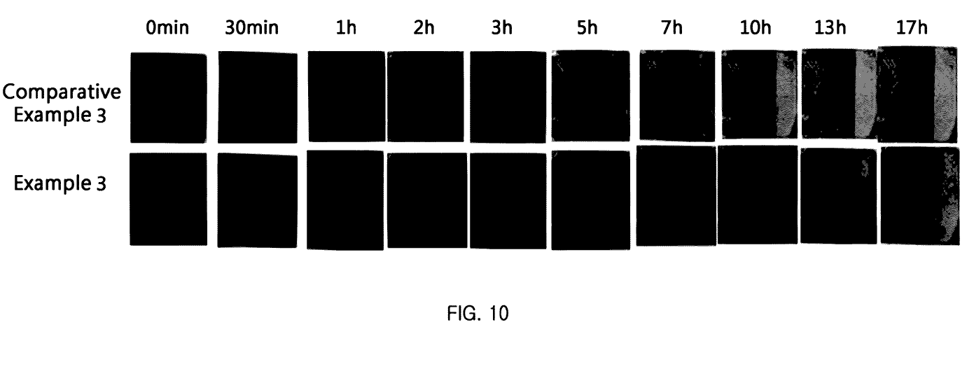

FIG. 10 shows images showing changes in the surface morphology of the organic-inorganic hybrid photovoltaic films produced in Example 3 and Comparative Example 3 at 85% RH and 25° C. in the dark as a function of exposure time to moisture (0-17 h).

As shown in FIG. 10, the surface morphology of the organic-inorganic hybrid photovoltaic film of Comparative Example 3 began to change at 3 h after exposure to moisture while that of the organic-inorganic hybrid photovoltaic film of Example 3 began to change at 7 h after exposure to moisture.

Furthermore, the surface morphology of the organic-inorganic hybrid photovoltaic film of Comparative Example 3 was changed suddenly whereas that of the organic-inorganic hybrid photovoltaic film of Example 3 was changed slowly.

### EVALUATION EXAMPLE 4

The micro-scale surface morphologies of the organic-inorganic hybrid photovoltaic films produced in Example 3 and Comparative Example 3 were analyzed by scanning electron microscopy and atomic force microscopy at 85% RH and 25° C. in the dark in order to investigate the influence of humidity on the inventive organic-inorganic hybrid photovoltaic film.

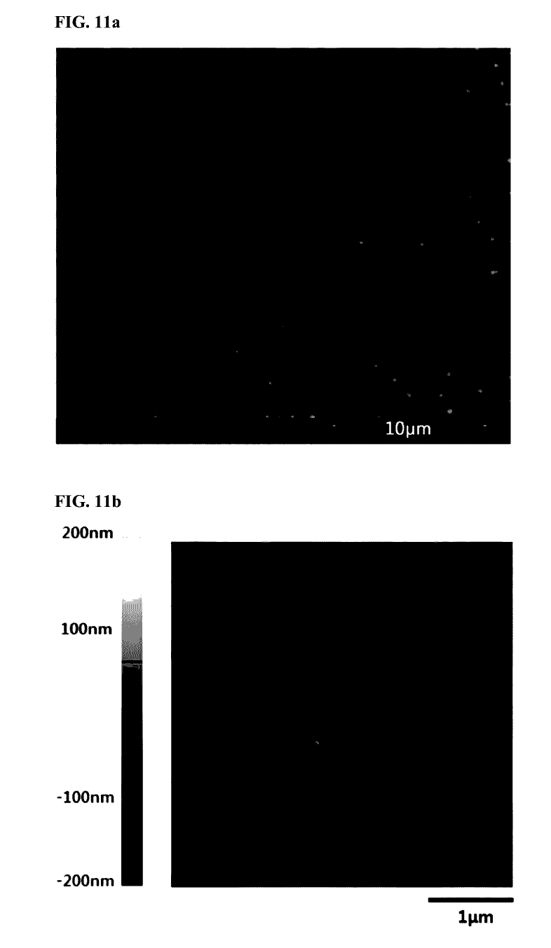

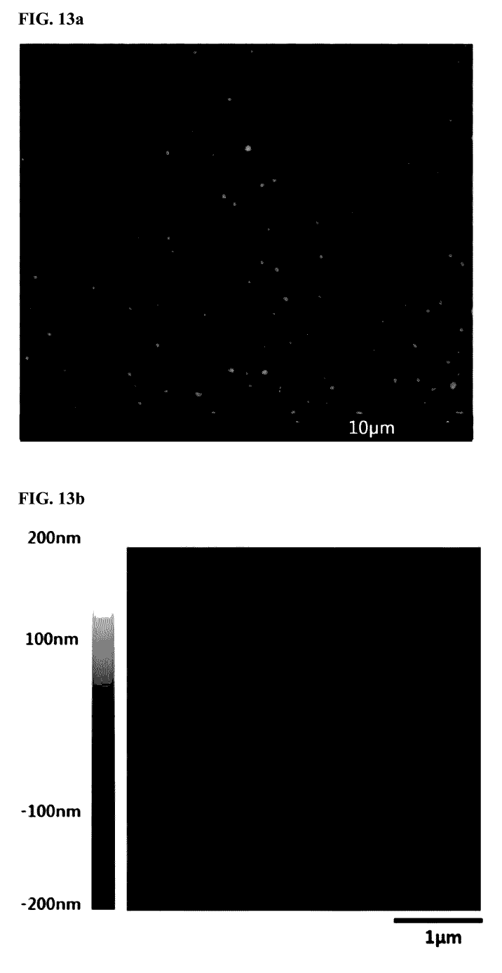

FIGS. 11 and 13 show (a) scanning electron microscopy images and (b) atomic force microscopy images of the organic-inorganic hybrid photovoltaic films produced in Comparative Example 3 and Example 3 before exposure to moisture, respectively.

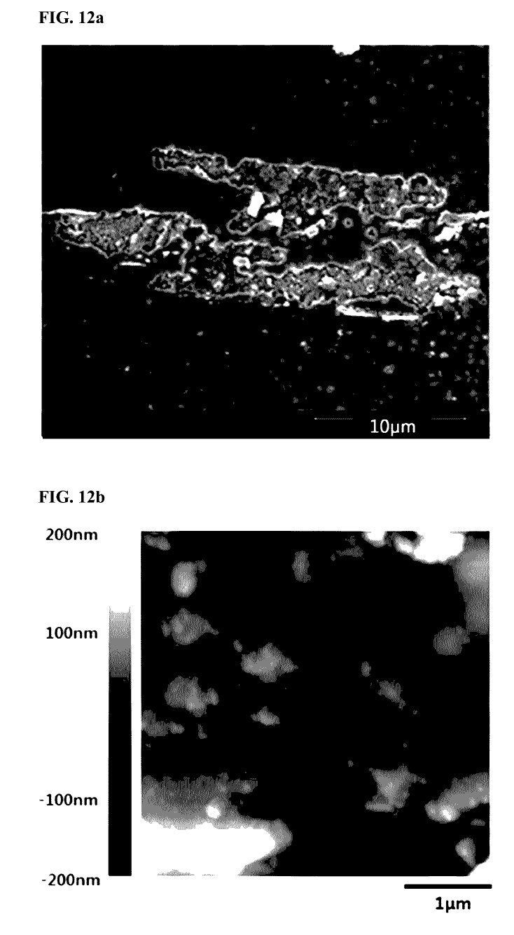

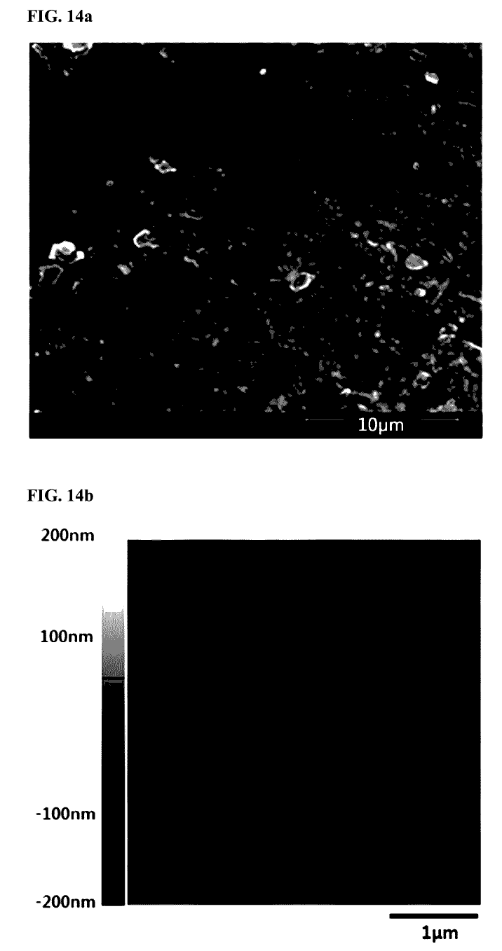

FIGS. 12 and 14 show (a) scanning electron microscopy images and (b) atomic force microscopy images of the organic-inorganic hybrid photovoltaic films produced in Comparative Example 3 and Example 3 after exposure to moisture for 19 days, respectively.

As shown in FIGS. 11 to 14, the hole transport layer of the organic-inorganic hybrid photovoltaic film fabricated in Comparative Example 3 had a root mean square surface roughness of 12.87 nm, revealing its smooth surface morphology (FIG. 11). After exposure to moisture for 19 days, the surface of the hole transport layer of the organic-inorganic hybrid photovoltaic film was observed. As a result, the surface of the hole transport layer was dug or cut out and the absorber layer was decomposed to the extent that the lower portion of the titanium dioxide (TiO₂) nanoparticle layer was seen (FIG. 12). The hole transport layer had a root mean square surface roughness of 67.64 nm, indicating that the moisture exposure led to increased surface roughness.

In contrast, the hole transport layer of the organic-inorganic hybrid photovoltaic film fabricated in Example 3 had a root mean square surface roughness of 4.4 nm, revealing its smooth surface morphology (FIG. 13). After exposure to moisture for 19 days, the surface of the hole transport layer of the organic-inorganic hybrid photovoltaic film was observed. As a result, the initial state of the hole transport layer remained almost unchanged (FIG. 14). That is, the hole transport layer of the organic-inorganic hybrid photovoltaic film was maintained in its initial state despite exposure to moisture for 19 days. As a result, an insignificant increase in the root mean square roughness of the hole transport layer was observed (12.28 nm).

In other words, the introduction of the moisture barrier film including the ionic polymer between the absorber layer and the hole transport layer is effective in blocking the ingress of moisture from the outside to protect the absorber layer and the hole transport layer while maintaining physical and chemical binding between the absorber layer and the hole transport layer.

What is claimed is:

1. A moisture barrier film for an organic-inorganic hybrid perovskite photovoltaic cell comprising an ionic polymer represented by Formula 1: 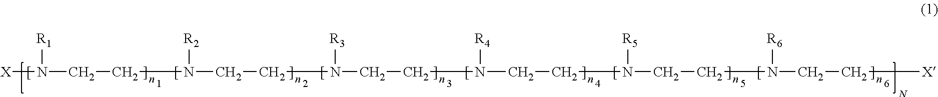
wherein X is selected from the group consisting of substituted or unsubstituted amino groups, C₁-C₄₀ alkylamino groups, and substituted or unsubstituted C₁-C₃₀ alkyl groups, X′ is selected from the group consisting of substituted or unsubstituted amino groups, C₁-C₄₀ alkylamino groups, and substituted or unsubstituted C₁-C₃₀ alkyl groups, R₁ to R₆ are identical to or different from each other and are each independently selected from the group consisting of a hydrogen atom, a carbonyl group, a hydroxyl group, a nitro group, an amino group, substituted or unsubstituted amino groups, and substituted or unsubstituted C₁-C₃₀ alkyl groups, n₁ to n₆ are each independently 1 or 0, with the proviso that at least one of n₁ to n₆ is 1, and N is an integer from 5 to 100,000, and wherein each substituent is independently selected from the group consisting of a deuterium atom, a hydrogen atom, a hydroxyl group, a nitro group, an amino group, straight or branched C₁-C₂₄ alkyl groups, C₁-C₄₀ alkylamino groups, and a carbonyl group.

2. The moisture barrier film according to claim 1, wherein the ionic polymer of Formula 1 is selected from the group consisting of the following structures of Formulae 2 to 19: 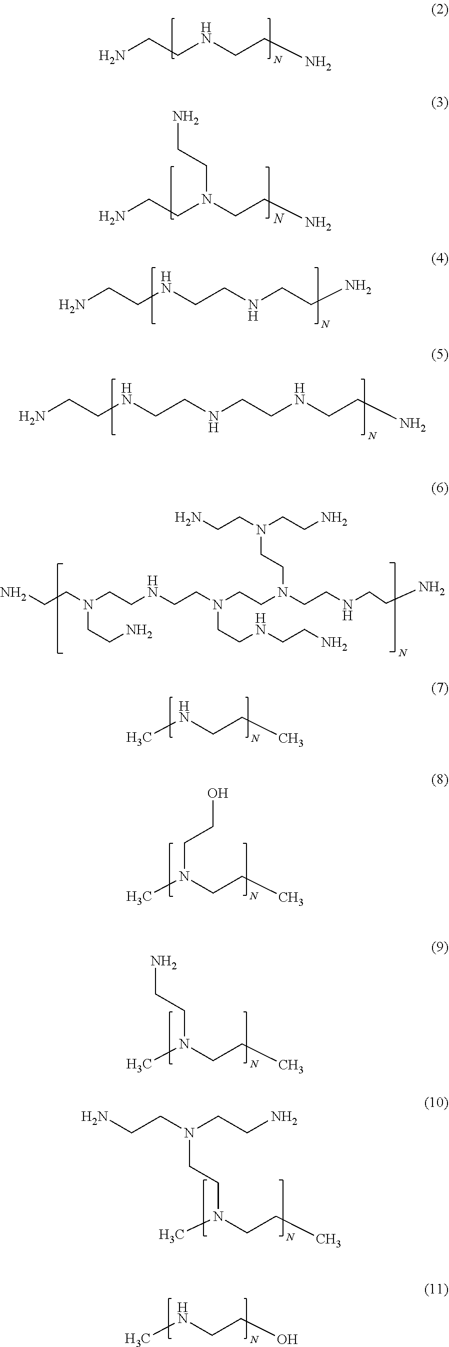 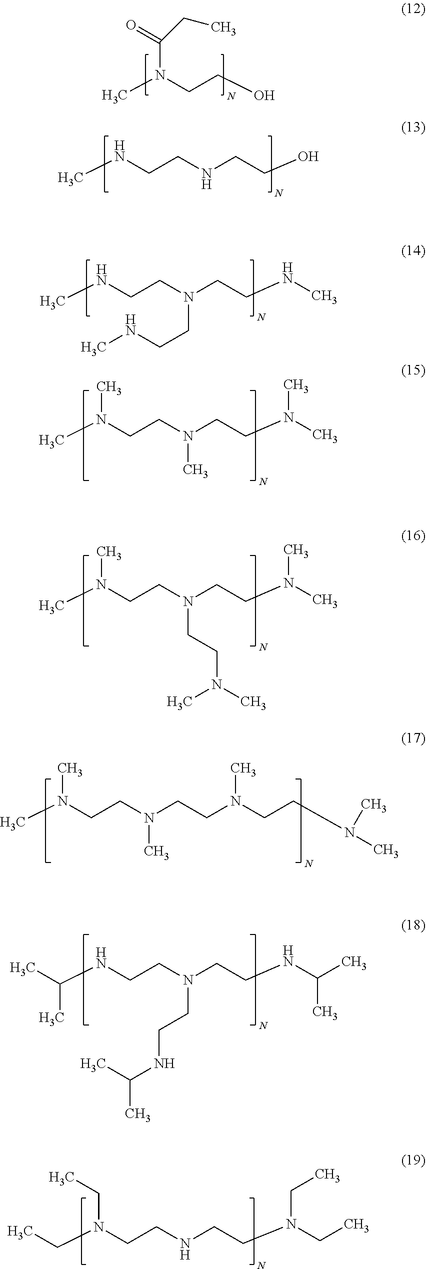
wherein each N is independently an integer from 5 to 100,000.

3. The moisture barrier film according to claim 1, wherein the moisture barrier film has a thickness of 1 to 60 nm.

4. The moisture barrier film according to claim 1, wherein the ionic polymer has a number average molecular weight of 1,000 to 1,000,000.

5. An organic-inorganic hybrid photovoltaic film comprising the moisture barrier film according to claim 1.

6. An organic-inorganic hybrid photovoltaic cell comprising the moisture barrier film according to claim 1.

7. The organic-inorganic hybrid photovoltaic cell according to claim 6, wherein portions of the moisture barrier film are infiltrated into pores formed in an absorber layer or a hole transport layer.

8. The organic-inorganic hybrid photovoltaic cell according to claim 6, wherein the moisture barrier film has a thickness of 10 to 60 nm.

9. The organic-inorganic hybrid photovoltaic cell according to claim 6, wherein the moisture barrier film has a multilayer structure.

10. The organic-inorganic hybrid photovoltaic cell according to claim 6, wherein the organic-inorganic hybrid photovoltaic cell maintains 39 to 80% of its initial energy conversion efficiency when exposed to a relative humidity of 70 to 90% for 15 to 25 days.
